(19) United States
(12) Patent Application Publication
(10) Pub. No.: US 2022/0224358 A1
(43) Pub. Date: Jul. 14, 2022

(54) POLAR CODE DECODING APPARATUS AND OPERATION METHOD THEREOF

(71) Applicant: National Tsing Hua University, Hsinchu City (TW)

(72) Inventors: Hsin-Yu Lee, Hsinchu City (TW); Yeong-Luh Ueng, Hsinchu City (TW); Yi-Han Pan, Hsinchu City (TW)

(73) Assignee: National Tsing Hua University, Hsinchu City (TW)

(21) Appl. No.: 17/575,598

(22) Filed: Jan. 13, 2022

(30) Foreign Application Priority Data
Jan. 14, 2021 (TW) 110101426

(51) Int. Cl. H03M 13/13; H03M 13/45; H03M 13/00

(52) U.S. Cl. CPC H03M 13/13; H03M 13/6583; H03M 13/45

(57) ABSTRACT

A polar code decoding apparatus and an operation method thereof are provided. The polar code decoding apparatus includes a path expanding circuit and a node processing circuit. The path expanding circuit expands each of multiple previous paths corresponding to multiple previous decoding results into multiple candidate paths according to a current node. The path expanding circuit dynamically determines a path expanding number of the candidate paths of each of the previous paths according to an unreliable information bit number of the current node. The node processing circuit performs a path competition operation to select some paths from the candidate paths to serve as multiple current paths corresponding to multiple current decoding results.

### CROSS-REFERENCE TO RELATED APPLICATION

This application claims the priority benefit of Taiwan application serial no. 110101426, filed on Jan. 14, 2021. The entirety of the above-mentioned patent application is hereby incorporated by reference herein and made a part of this specification.

### BACKGROUND

### Technical Field

This disclosure relates to a decoder, and in particular to a polar code decoding apparatus and an operation method thereof.

### Description of Conventional Technology

Polar codes are a type of forward error correction coding. The encoding method of the polar codes has been proven to achieve Shannon capacity. The polar codes have been adopted by the Third Generation Partnership Project (3GPP) as the coding for controlling channels in the fifth generation (5G) mobile communication technology. Main coding for the polar codes includes the Successive cancellation list (SCL) algorithm and the Belief propagation algorithm. SCL-based polar codes use list-based successive cancellation decoding algorithm to perform decoding. Although it can achieve good decoding results, it is not conducive for parallelization, and complexity of hardware implementation and decoding time delay are higher. Node-wise SCL decoding or multi-bit SCL decoding may decode multiple bits concurrently, which effectively reduces the complexity and the decoding delay. Therefore, they have become the main hardware implementation manners of the SCL-based polar codes.

An encoded bit string generates polarization of the channels after the polar codes are encoded, which enables some of the channels to become very reliable, while concurrently causing other channels to become very unreliable. Information (information bits, that is, bits with unknown values) that is to be transmitted may be placed on the reliable channels, and known information (frozen bits, that is, bits with known values) may be placed on the unreliable channels. For example, the value of the frozen bit may be fixed to logic “0”.

The successive cancellation list decoding method based on nodes, divides the bit string into multiple sub-bit strings, and each of the sub-bit strings may be regarded as a node. The decoding hardware may process one node (one sub-bit string) at a time. The Fast simplified SCL (Fast-SCCL) algorithm may be applied to the decoder in order to reduce the complexity. Each node is classified into at least four types of nodes based on the number and distribution of its information bits, such as a Rate-0 node, a Rep node, a Rate-1 node and a single parity check (SPC) node. In the Rate-0 node, each bit is a frozen bit. In the Rep node, only the last bit is an information bit, while the remaining bits are frozen bits. In the Rate-1 node, each bit is an information bit. In the SPC node, only the first bit is a frozen bit, while the remaining bits are information bits. Nodes of the same type have the same decoding process. Nodes that cannot be classified into the four types are called maximum likelihood (ML) nodes.

During the node-wise successive cancellation list decoding, assume that the list size is L and the path expanding number is E. That is, each expansion of the L paths is E candidate paths. During the processing of each of the nodes, a conventional decoder have to select a best L path from E*L expanded paths (candidate paths). A path expanding number E of each of the nodes may not be the same. In general, the size of the path expanding number E is between 1 and 2¹, where I is the information bit number contained in the node. In the conventional technology, the nodes of the same type have the same decoding process, and each of the nodes has the same path expanding number E, regardless of the position of the node.

In order to perform a path competition operation on the E*L candidate paths, an E*L-to-L sorter is generally required. A lot of hardware resources and time are consumed to implement the E*L-to-L sorter. Therefore, in practice, an E−1 path competition operation is executed through a 2L-to-L sorter in the conventional technology to achieve “the path competition operation being performed on the E*L candidate paths”.

The information bit numbers contained in the Rate-0 node and the Rep node are 0 and 1. Therefore, the Rate-0 node and the Rep node are easy to process. As for the Rate-1 node and the SPC node having many information bits, a lot of time is consumed if a 2L-to-L sorter is used to perform the E−1 path competition operation. Therefore, restrictions are imposed on the Rate-1 node and the SPC node in the conventional technology, even if the path expanding number E of the Rate-1 node and the SPC node are respectively equal to 2^{min(L-1,M)} and 2^{min(L,M-1)}, where L is the list size, and M is the node size (the bit number of the node).

During the path competition operation, the conventional decoder uses path metric value (PM) to measure the reliability of the candidate path. In the hardware implementation, a clock frequency mainly depends on a length of a critical path. In a conventional polar code decoder, the critical path is often located in the process of “calculating and sorting the path metric values”. If this part can be optimized, the clock frequency may be further increased, thereby increasing throughput of communication transmission.

It should be noted that the content in the “related art” is used to facilitate understanding of the disclosure. Part of the content (or all of the content) disclosed in the “related art” may not be the conventional technology known to those with ordinary knowledge in the technical field. The content disclosed in the “related art” does not mean that the content has been known to those with ordinary knowledge in the technical field before the patent application.

### SUMMARY

This disclosure provides a polar code decoding apparatus and an operation method thereof to perform polar code decoding on an encoded bit string.

In an embodiment of the disclosure, the polar code decoding apparatus includes a path expanding circuit and a node processing circuit. The path expanding circuit is configured to expand each of multiple previous paths corresponding to multiple previous decoding results into multiple candidate paths according to a current node. The encoded bit string is divided into multiple sub-bit strings to serve as multiple nodes including the current node. The path expanding circuit is configured to dynamically determine a path expanding number of the candidate paths for each of the previous paths according to an unreliable information bit number of the current node. The node processing circuit is coupled to the path expanding circuit. The node processing circuit is configured to perform a path competition operation to select some paths from the candidate paths to serve as multiple current paths corresponding to multiple current decoding results.

In an embodiment of the disclosure, the operation method includes the following steps. Each of multiple previous paths corresponding to multiple previous decoding results is expanded into multiple candidate paths by a path expanding circuit according to a current node. A path expanding number of the candidate paths of each of the previous paths is dynamically determined by the path expanding circuit according to an unreliable information bit number of the current node. A path competition operation is performed by a node processing circuit to select some paths from the candidate paths to serve as multiple current paths corresponding to multiple current decoding results.

Based on the foregoing, the polar code decoding apparatus and the operation method thereof according to the embodiments of the disclosure can optimize the efficiency of polar code decoding to a maximum extent. The nodes at the different positions will have different reliabilities. The term “reliability” is an inherent difference caused by the polarization of the polar code channels. A node containing many reliable information bits is not required to expand into many candidate paths. In the case where “nodes with different reliabilities have the same path expanding number”, the path expanding circuit may perform expansion of redundant paths (expand out into redundant candidate paths). It is conceivable that the redundant candidate paths will increase the hardware complexity and decoding delay. Therefore, in some embodiments, the path expanding circuit may dynamically determine the path expanding number of each of the previous paths according to the unreliable information bit number of the current node, so as to reduce the redundant candidate paths as much as possible.

In an embodiment of the disclosure, the polar code decoding apparatus includes a path expanding circuit and a node processing circuit. The path expanding circuit is configured to expand each of multiple previous paths corresponding to multiple previous decoding results into multiple candidate paths according to a current node. The node processing circuit is coupled to the path expanding circuit. The node processing circuit is configured to perform a path competition operation to select some paths from the candidate paths to serve as multiple current paths corresponding to multiple current decoding results. The path competition operation performed by the node processing circuit includes selecting some paths from the candidate paths to serve as the current paths according to a path metric value of each of the previous paths and a log-likelihood ratio (LLR) value of each of multiple bits of the current node.

In an embodiment of the disclosure, the operation method includes the following steps. Each of multiple previous paths corresponding to multiple previous decoding results is expanded into multiple candidate paths by a path expanding circuit according to a current node. A path competition operation is performed by the node processing circuit to select some paths from the candidate paths to serve as multiple current paths corresponding to multiple current decoding results. The path competition operation performed by the node processing circuit includes selecting some paths from the candidate paths to serve as the current paths according to a path metric value of each of the previous paths and a LLR value of each of multiple bits of the current node.

Based on the foregoing, the polar code decoding apparatus and the operation method thereof according to the embodiments of the disclosure can optimize the efficiency of polar code decoding to a maximum extent. The node processing circuit has to process all of the candidate paths when the node processing circuit performs the path competition operation in an irregular manner. The polar code decoding apparatus may preferentially select a more reliable candidate path to undergo the path competition operation according to the path metric values of the previous paths and the LLR value of the current node. The LLR value here is the LLR value of each dynamic bit received by the node from the channel end. For example, some embodiments may perform offline statistical analysis on the node according to the bit reliability, so as to sort the flipping pattern that is more likely to be the correct path in the position prioritized for sorting. The polar code decoding apparatus may determine the path to be compared in the next stage according to the flipping pattern and the surviving path from the previous stage. Therefore, the polar code decoding apparatus can accurately and efficiently find out which of the candidate paths are more likely to be the correct paths.

In an embodiment of the disclosure, the polar code decoding apparatus includes a path expanding circuit and a node processing circuit. The path expanding circuit is configured to expand each of multiple previous paths corresponding to multiple previous decoding results into multiple candidate paths according to a current node. The node processing circuit is configured to perform a path competition operation to select some paths from the candidate paths to serve as multiple current paths corresponding to multiple current decoding results. The path competition operation performed by the node processing circuit includes the following steps. At least one candidate path is selected from the candidate paths of each of the previous paths to serve as multiple first candidate paths. A path metric value of each of the first candidate paths is calculated. Some paths are selected from the first candidate paths to serve as multiple first surviving paths according to the path metric values of the first candidate paths. A normalization operation is performed on the path metric values of multiple final surviving paths.

In an embodiment of the disclosure, the operation method includes the following steps. Each of multiple previous paths corresponding to multiple previous decoding results is expanded into multiple candidate paths by a path expanding circuit according to a current node. A path competition operation is performed by a node processing circuit to select some paths from the candidate paths to serve as multiple current paths corresponding to multiple current decoding results. The path competition operation performed by the node processing circuit includes the following steps. At least one candidate path is selected from the candidate paths of each of the previous paths to serve as multiple first candidate paths. A path metric value of each of the first candidate paths is calculated. Some paths are selected from the first candidate paths to serve as multiple first surviving paths according to the path metric values of the first candidate paths. A normalization operation is performed on the path metric values of multiple final surviving paths.

Based on the foregoing, the polar code decoding apparatus and the operation method thereof according to the embodiments of the disclosure can optimize the efficiency of polar code decoding to a maximum extent. The length of the critical path is related to the bit number of the path metric value. In some embodiments, the node processing circuit may perform the normalization operation on the path metric value of the candidate path (the final surviving path) that survives the last stage to reduce the bit number of the path metric value. In other embodiments, the node processing circuit may perform the normalization operation on the path metric value of the candidate path that survives each stage to reduce the bit number of the path metric value.

To make the abovementioned more comprehensible, several embodiments accompanied by drawings are described in detail as follows.

### BRIEF DESCRIPTION OF THE DRAWINGS

FIG. 1 is a schematic circuit block diagram of a polar code decoding apparatus according to an embodiment of the disclosure.

FIG. 2 is a schematic diagram illustrating the path expanding circuit and the node processing circuit in FIG. 1 performing a path expanding operation and a path competition operation according to an embodiment of the disclosure.

FIG. 3 is a schematic flowchart of an operation method of the polar code decoding apparatus according to an embodiment of the disclosure.

FIG. 4 is a schematic flowchart of an operation method of the polar code decoding apparatus according to another embodiment of the disclosure.

FIGS. 5A to 5C are schematic diagrams illustrating the operation process of performing the path competition operation on the candidate paths expanded from the previous paths shown in FIG. 2 according to an embodiment of the disclosure.

FIGS. 6A to 6C are schematic diagrams illustrating a specific process of performing the path competition operation on the sorted candidate paths according to an embodiment of the disclosure.

FIG. 7 is a schematic flowchart of an operation method of the polar code decoding apparatus according to yet another embodiment of the disclosure.

FIG. 8 is a schematic circuit block diagram illustrating the interface circuit, the path expanding circuit, and the node processing circuit shown in FIG. 1 according to an embodiment of the disclosure.

### DESCRIPTION OF THE EMBODIMENTS

The terms “coupled” or “connected” used in the full text of this specification (including the scope of the patent application) can refer to any direct or indirect means of connection. For example, if the first device is being described as coupled (or connected) to the second device, it should be interpreted as that the first device may be directly connected to the second device, or the first device may be indirectly connected to the second device through another device or some types of connection means. Terms such as “first” and “second” mentioned in the specification (including the scope of the patent application) are used to name the elements, or to distinguish between different embodiments or ranges, and are not intended to limit an upper limit or a lower limit of the number of the elements, or to limit the order of the elements. In addition, wherever possible, elements/components/steps with the same reference numerals in the drawings and embodiments represent the same or similar parts. Reference may be made to the relevant descriptions of the elements/components/steps using the same reference numerals or using the same terms in different embodiments.

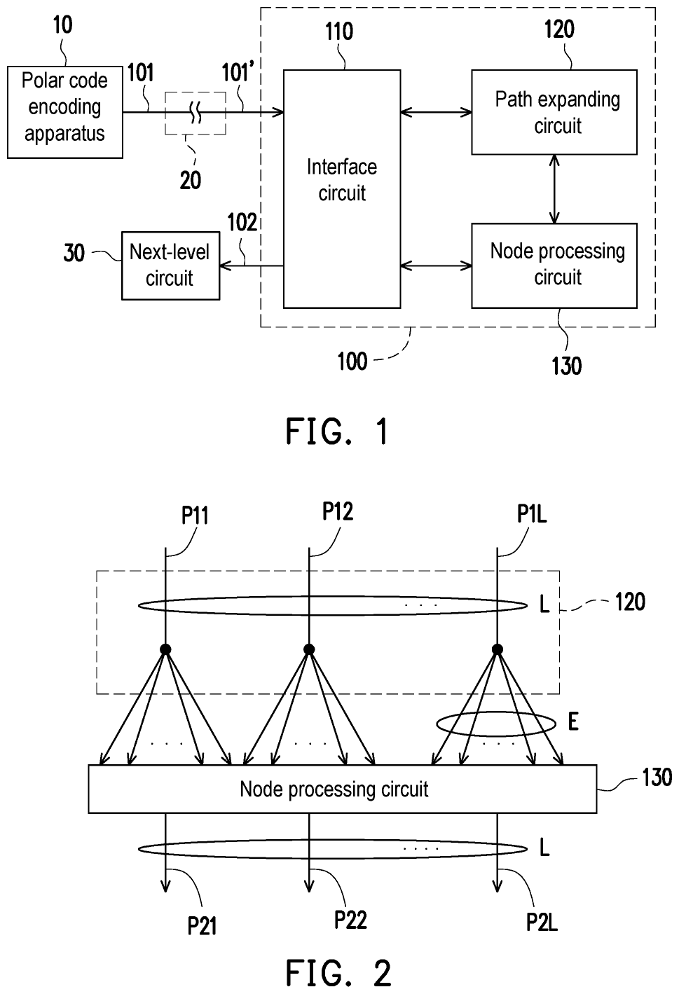

FIG. 1 is a schematic circuit block diagram of a polar code decoding apparatus 100 according to an embodiment of the disclosure. A polar code encoding apparatus 10 may generate an encoded bit string 101 and transmit it to a communication channel 20. The encoded bit string 101 outputted by the polar code coding apparatus 10 may be polluted by noise and becomes an encoded bit string 101′ during transmission by the communication channel 20. The polar code decoding apparatus 100 shown in FIG. 1 includes an interface circuit 110, a path expanding circuit 120, and a node processing circuit 130. The interface circuit 110 may receive the noise-polluted encoded bit string 101′ from the communication channel 20. The polar code decoding apparatus 100 is suitable for performing decoding of the noise-polluted encoded bit string 101′, and then output a decoded bit string 102 to a next-level circuit 30. For example, the polar code decoding apparatus 100 may perform a node-wise Successive cancellation list decoding (node-wise SCL decoding) algorithm and/or other polar code decoding algorithms. The encoded bit string (101′ and/or 101) is divided into multiple sub-bit strings. The sub-bit strings serve as multiple nodes. The node-wise SCL decoding may concurrently decode multiple bits (that is, one node) at a time.

FIG. 2 is a schematic diagram illustrating the path expanding circuit and the node processing circuit in FIG. 1 performing a path expanding operation and a path competition operation according to an embodiment of the disclosure. With reference to FIGS. 1 and 2, in an operation batch, the interface circuit 110 may provide one of the nodes (a current node) to the path expanding circuit 120. Paths P11, P12, . . . , P1L shown in FIG. 2 represent L previous paths corresponding to previous candidate decoding results of a previous node, where L is a list size. The list size L may be any integer defined according to design requirements. The path expanding circuit 120 may expand each of the previous paths P11 to P1L into multiple candidate paths according to the current node. For example, the path expanding circuit 120 may expand the previous path P1L into E candidate paths, where E is the path expanding number. The path expanding number E may be any integer defined according to the design requirements.

The node processing circuit 130 may perform a path competition operation on the candidate paths of the previous paths P11 to P1L, so as to select L paths from the candidate paths to serve as current paths P21, P22, . . . , P2L. The current paths P21 to P2L correspond to multiple candidate decoding results of the current node. The paths P21 to P2L corresponding to the current node may serve as the previous paths P11 to P1L corresponding to a next node during decoding of the next node after the current node.

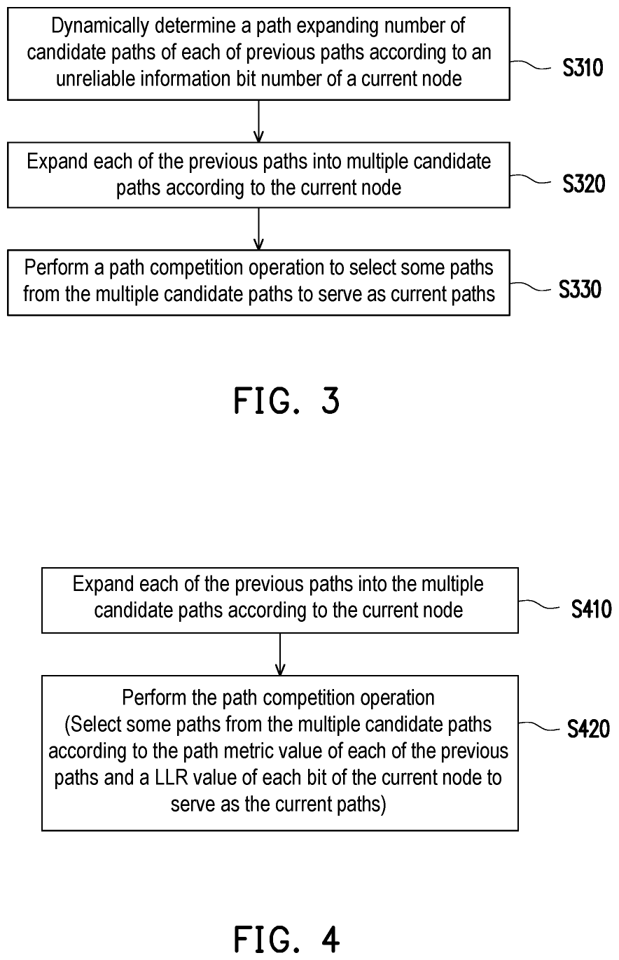

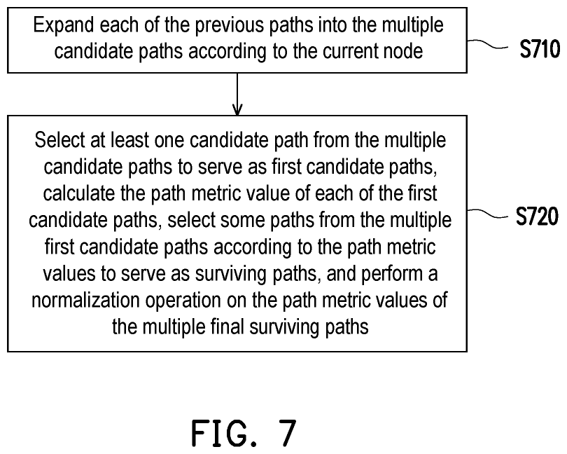

In some embodiments, the path expanding circuit 120 may adaptively determine the path expanding number E (with reference to relevant description of FIG. 3) according to an unreliable information bit number c of the current node, and then expand each of the L previous paths P11 to P1L into the E candidate paths according to the current node. In some embodiments, the node processing circuit 130 may perform the path competition operation (with reference to relevant description of FIG. 4) according to a path metric value (PM) of each of the previous paths P11 to P1L and a bit reliability of each of the bits of the current node, so as to select some paths from the candidate paths to serve as L current paths P21 to P2L. The “bit reliability” here is reliability of each dynamic bit received by the node from a channel end, such as a log-likelihood ratio (LLR). For example, some embodiments may perform offline statistical analysis on the node according to the bit reliability, so as to sort a flipping pattern that is more likely to be a correct path in a position prioritized for sorting. The polar code decoding apparatus may determine a path to be compared in a next stage according to the flipping pattern and a surviving path from a previous stage. In some embodiments, the node processing circuit 130 may calculate the path metric value PM of some of the candidate paths that are being processed currently, and then select some paths from the candidate paths that are being processed currently according to the path metric values PMs to serve as surviving paths during the path competition operation. Final L surviving paths P21 to P2L may serve as current paths corresponding to current decoding results after the path competition operation is completed, and the node processing circuit 130 may perform normalization (with reference to relevant description of FIG. 7) on the path metric values PMs of the L surviving paths. The interface circuit 110 may output the decoded bit string 102 to the next-level circuit 30 based on processing results of each of the nodes.

FIG. 3 is a schematic flowchart of an operation method of the polar code decoding apparatus according to an embodiment of the disclosure. With reference to FIGS. 1 to 3, the encoded bit string (101′ and/or 101) may be divided into the multiple sub-bit strings based on an polar code encoding operation of the polar code encoding apparatus 10, and the sub-bit strings may serve as the multiple nodes including the current node. In Step S310, the path expanding circuit 120 may dynamically determine the path expanding number E of the multiple candidate paths of each of the multiple previous paths P11 to P1L corresponding to the multiple previous decoding results according to the unreliable information bit number c of the current node.

The unreliable information bit number c is described as follows. The encoded bit string 101 contains multiple information bits (that is, bits with unknown values) and multiple frozen bits (that is, bits with known values), after the polar code encoding operation is completed. The polar code encoding apparatus 10 may provide the polar code decoding apparatus 100 with the bit reliability of each of the bits in the encoded bit string 101. This embodiment does not limit specific implementation of the bit reliability. In some embodiments, the bit reliability may include a well-known Bhattacharyya parameter or other values suitable for showing the reliability of each of the bits in the encoded bit string 101 according to the design requirements.

Each of the bits in the encoded bit string 101 has a corresponding bit reliability. Each of the bits in the encoded bit string 101 may be classified as an “information bit” or a “frozen bit” according to the bit reliability, based on the polar code encoding operation of the polar code encoding apparatus 10. Specifically, a numerical range of the bit reliability may at least be divided into a first sub-range and a second sub-range. The first sub-range is a partial numerical range with highest reliability in the numerical range, and the second sub-range is a partial numerical range with lowest reliability in the numerical range. A certain bit (current bit) may be classified as an “information bit” when the bit reliability of the current bit in the encoded bit string 101 falls within the first sub-range. The current bit may be classified as a “frozen bit” when the bit reliability of the current bit falls within the second sub-range.

Sizes of the first sub-range and the second sub-range may be determined according to the design requirements. For example (but not limited to this), the first sub-range may be first 50% of the numerical range of the bit reliability, and the second sub-range may be last 50% of the numerical range of the bit reliability. The “first 50%” means the 50% with the highest reliability in the numerical range. Similarly, the “last 50%” is the 50% with the lowest reliability in the numerical range.

The first sub-range may at least be divided into a third sub-range and a fourth sub-range. The third sub-range is a partial numerical range with highest reliability in the first sub-range, and the fourth sub-range is a partial numerical range with lowest reliability in the first sub-range. The current bit may be classified as a “reliable information bit” when the bit reliability of the current bit falls within the third sub-range. The current bit may be classified as an “unreliable information bit” when the bit reliability of the current bit falls within the fourth sub-range. Sizes of the third sub-range and the fourth sub-range may be determined according to the design requirements. For example (but not limited to this), the third sub-range may be first 72.54% of the first sub-range, and the fourth sub-range may be remaining 27.46% of the first sub-range.

The unreliable information bit number c of the current node may be a number of the bits classified as “unreliable information bits” in the current node. In the Step S310, the path expanding circuit 120 may dynamically determine the path expanding number E of the candidate paths of each of the L previous paths P11 to P1L according to the unreliable information bit number c of the current node. For example (but not limited to this), the path expanding number E=min (2^{ε}, L), where min( ) represents a “minimum value” function, E represents the number of the bits classified as the “unreliable information bits” in the current node, and L represents a path number of the previous paths P11 to P1L (or a path number of the current paths P21 to P2L).

With reference to FIGS. 1 to 3, in Step S320, the path expanding circuit 120 may expand each of the L previous paths P11 to P1L corresponding to the previous decoding results into the multiple candidate paths according to the current node. For example, the path expanding circuit 120 may expand the previous path P1L into the E candidate paths, where the path expanding number E of the candidate paths is min (2^{ε}, L). The embodiment does not limit specific implementation of the path expanding operation performed in the Step S320. In some embodiments, the path expanding operation performed in the Step S320 may be a path expanding operation in a conventional polar code decoding algorithm according to the design requirements. In other embodiments, the Step S320 may perform other path expanding operations.

The node processing circuit 130 is coupled to the path expanding circuit 120. In Step S330, the node processing circuit 130 may perform the path competition operation to select some paths from the multiple candidate paths expanded from the previous paths P11 to P1L to serve as the L current paths P21 to P2L corresponding to the current decoding results. The embodiment does not limit specific implementation of the path competition operation performed in the Step S330. In some embodiments, according to the design requirements, the path competition operation performed in the Step S330 may be a path competition operation in the conventional polar code decoding algorithm. In other embodiments, the Step S330 may perform other path competition operations, such as a path competition operation performed in Step S420 as shown in FIG. 4. The interface circuit 110 may output the decoded bit string 102 to the next-level circuit 30 based on the processing results of each of the nodes.

FIG. 4 is a schematic flowchart of an operation method of the polar code decoding apparatus according to another embodiment of the disclosure. With reference to FIGS. 1 and 4, in Step S410, the path expanding circuit 120 may expand each of the multiple previous paths P11 to P1L corresponding to the previous decoding results into the multiple candidate paths according to the current node. According to the design requirements, reference may be made to the relevant description of the Step S320 shown in FIG. 3 for the Step S410 shown in FIG. 4, and (or) reference may be made to relevant description of the Step S410 shown in FIG. 4 for the Step S320 shown in FIG. 3. In some embodiments, the path expanding number E of a path expanding operation performed in the Step S410 shown in FIG. 4 may be min (2^{ε}, L) (with reference to the relevant description of the Step S310 shown in FIG. 3). In other embodiments, the path expanding number E of the path expanding operation performed in the Step S410 shown in FIG. 4 may be 2^{min (L-1,M)}, 2^{min (L,M-1)}, or other numbers.

With reference to FIGS. 1, 2 and 4, since a number E*L of the candidate paths is reduced, the Step S420 may perform a more efficient sorting to accurately find out which of the candidate paths are more likely to be the correct path, thereby selecting only these candidate paths for path competition. In the Step S420, the node processing circuit 130 may perform the path competition operation to select some paths from the candidate paths expanded from the previous paths P11 to P1L to serve as the multiple current paths P21 to P2L corresponding to the current decoding results. The path competition operation performed by the node processing circuit 130 in the Step S420 may include selecting some paths from the candidate paths to serve as the current paths P21 to P2L according to the path metric value PM of each of the previous paths P11 to P1L and a LLR value of each of the bits of the current node. According to the design requirements, reference may be made to the relevant description of the Step S420 shown in FIG. 4 for the Step S330 shown in FIG. 3.

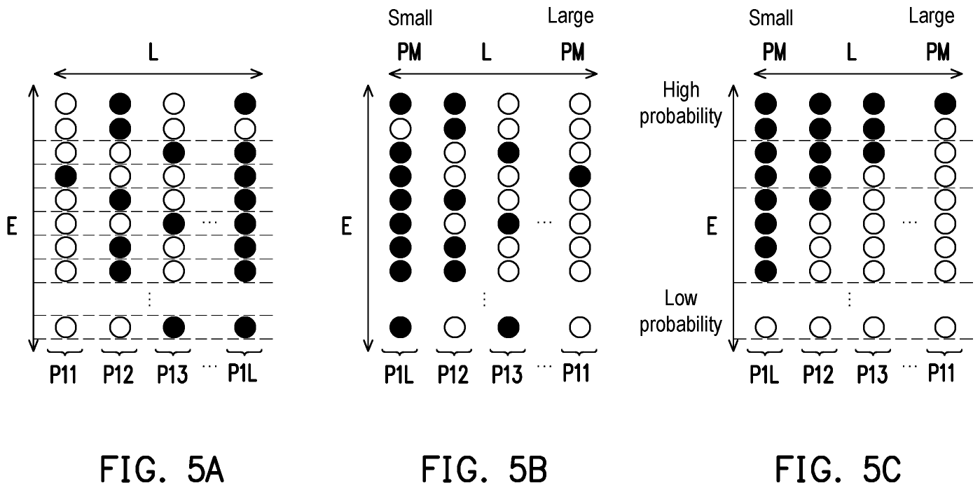

FIGS. 5A to 5C are schematic diagrams illustrating the operation process of performing the path competition operation on the candidate paths expanded from the previous paths P11 to P1L shown in FIG. 2 according to an embodiment of the disclosure. The node processing circuit 130 may perform the path competition operation shown in FIGS. 5A to 5C in the Step S420.

A small circle shown in FIG. 5A represents the E candidate paths expanded from each of the previous paths P11 to P1L. A solid circle represents a candidate path that survived the decoding, and a hollow circle represents a candidate path that was not selected in the decoding. The decoder may calculate the LLR value of each of the bits in the noise-polluted encoded bit string 101′, and send the LLR values to the node. The LLR values may be used to calculate the corresponding path metric value PM of each of the paths, and the path metric value PM may represent a survival likelihood of the candidate path. In FIG. 5A, the E candidate paths in a first column are the candidate paths expanded from the previous path P11, the E candidate paths in a second column are the candidate paths expanded from the previous path P12, the E candidate paths in a third column are the candidate paths expanded from the previous path P13, and the E candidate paths in a L-th column are the candidate paths expanded from the previous path P1L.

It can be seen from FIG. 5A that distribution of the surviving paths is very irregular. The node processing circuit 130 may sort the previous paths P11 to P1L shown in FIG. 5A according to the path metric values PMs of the previous paths P11 to P1L. The sorted results of the previous paths P11 to P1L are shown in FIG. 5B. As an example, in the embodiment shown in FIG. 5B, the E candidate paths expanded from a parent path (previous path) with a smaller path metric value PM has a higher chance of survival. In other embodiments, the definition of the path metric value PM may be different from that shown in FIG. 5B.

The node processing circuit 130 may sort the candidate paths of each of the previous paths P11 to P1L after the sorting of the previous paths P11 to P1L (as shown in FIG. 5B) is completed. The sorted results of the candidate paths are shown in FIG. 5C. The node processing circuit 130 may sort the candidate paths of each of the previous paths P11 to P1L according to the flipping pattern corresponding to the current node type and the LLR values of the bits of the current node to determine a “selection order” of the candidate paths. The candidate paths with a higher probability of survival are sorted as “preferred selection”, as shown in FIG. 5C. The node processing circuit 130 may predict that the candidate paths nearer upper left of FIG. 5C are more likely to survive, and preferentially select these candidate paths to undergo the path competition. Therefore, the embodiment shown in FIGS. 5A to 5C may execute a sub-path competition operation through a 2L-to-L sorter, as compared to the conventional technology of using the 2L-to-L sorter to perform an E−1 path competition operation to achieve “performing the path competition operation on the E*L candidate paths”. The number of 2L-to-L sorting (path competition operations) is reduced from E−1 to log₂ E, which means that the polar code decoding apparatus 100 may accurately and more efficiently find out which of the candidate paths are more likely to be the correct path.

The embodiment uses the flipping pattern to sort the E paths expanded from a certain previous path. The flipping pattern is a combination of the multiple bits of a node. In the embodiment, offline statistical analysis may be performed on each type of the nodes, so as to sort the flipping pattern that is more likely to be the correct path in a position prioritized for sorting. For example, assuming that a node has 2 bits, the flipping pattern includes “all bits are not flipped”, “only one bit is flipped and a most unreliable (smallest LLR) position is flipped”, “only one bit is flipped and a second most unreliable (second smallest LLR) position is flipped” and “both bits are flipped”. If the LLR value of the current node is (−0.5,5), a first path (first in the order) in the selection order of the flipping pattern of the current node is (1,0), a second path (second in the order) in the selection order is (0,0), a third path (third in the order) in the selection order is (1,1), and a fourth path (fourth in the order) in the selection order is (0,1). The flipping pattern is analyzed and fixed in advance, but the actual expanded paths are related to the LLR value received by the current node.

The node processing circuit 130 may preferentially select a more likely to be correct candidate path to undergo the path competition operation after the path metric values PMs of the parent paths (the previous paths P11 to P1L) and the flipping pattern of the current node are sorted. A concept of this type of path competition operation is that the candidate path (flipping pattern) to undergo the path competition operation in a next stage (step) is determined by the candidate paths that survive the current stage. The node processing circuit 130 may select first two types of the flipping patterns (candidate paths) of a highest possibility for each of the parent paths (the previous paths P11 to P1L) to undergo 2L-to-L path competition in a first stage. That is, the node processing circuit 130 may preferentially select 2L candidate paths that are more likely to survive to undergo the path competition, and then obtain the L surviving paths when the number of the parent paths is L. Assuming that a surviving path is located at an i-th position in the selection order (an i-th position of the flipping pattern), the candidate path expanded from the same parent path at a k-th stage is located in an i+2^{(k-1)}th position (an i+2^{(k-1)}th position of the flipping pattern). The node processing circuit 130 may complete the path competition of a node (the current node) after log₂ E “2L-to-L path competition”.

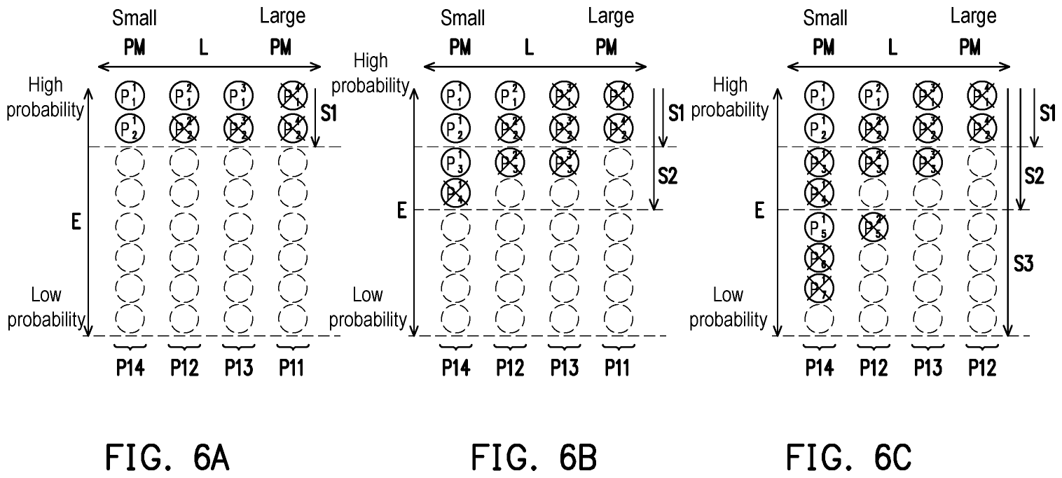

For example, FIGS. 6A to 6C are schematic diagrams illustrating a specific process of performing path competition operations on the sorted candidate paths according to an embodiment of the disclosure. The operation example shown in FIGS. 6A to 6C assumes that the list size L is 4, and the path expanding number E of each of the parent paths (the previous paths P11 to P1L) is 8. In the operation example shown in FIGS. 6A to 6C, the candidate paths of an x-th column and an y-th row is recorded as P_{y}^{x}. The node processing circuit 130 may sort the candidate paths of each of the previous paths P11, P12, P13, and P14 according to the LLR values of all of the bits of the current node, so as to determine the selection order (deduce with reference to relevant descriptions of FIGS. 5A and 5C) of the candidate paths of each of the previous paths P11 to P14. At least one candidate path is selected from the candidate paths of each of the previous paths P11 to P14 according to the selection order of each of the previous paths P11 to P14 to serve as multiple first candidate paths.

In a first stage S1 shown in FIG. 6A, the node processing circuit 130 may extract the first two flipping patterns (the first candidate paths) in the selection order for each of the parent paths (the previous path P11 to P14) to undergo an “8-to-4 (2L-to-L) path competition”. That is, eight candidate paths P₁¹, P₁², P₁³, P₁⁴, P₂¹, P₂², P₂³ and P₂⁴ are extracted to undergo the path competition. In the path competition operation, the node processing circuit 130 may calculate the path metric value PM of each of the first candidate paths P₁¹, P₁², P₁³, P₁⁴, P₂¹, P₂², P₂³ and P₂⁴. The embodiment does not limit a specific calculation manner of the path metric value PM. In some embodiments, according to the design requirements, the calculation manner of the path metric value PM may be a path metric value calculating operation in the conventional polar code decoding algorithm. In other embodiments, the calculation manner of the path metric value PM may be other metric value calculating operations. The node processing circuit 130 may select some paths from the first candidate paths P₁¹, P₁², P₁³, P₁⁴, P₂¹, P₂², P₂³ and P₂⁴ according to the path metric values PMs of the first candidate paths P₁¹, P₁², P₁³, P₁⁴, P₂¹, P₂², P₂³ and P₂⁴ to serve as multiple first surviving paths. The number of the first surviving paths is same as the path number of the previous paths P11 to P14 (or the current paths P21 to P2L). It is assumed here that the candidate paths P₁¹, P₁², P₁³, and P₂¹ survive after the path competition, as shown in FIG. 6A.

In a case where a certain path (herein called a target surviving path) of the first surviving paths P₁¹, P₁², P₁³, and P₂¹ belongs to a certain path (herein called a target previous path) of the previous paths P11 to P14, the node processing circuit 130 may select an unselected candidate path from the candidate paths of the target previous path according to the selection order of the target previous path to serve as one of multiple second candidate paths in a second stage S2. The second candidate paths also include the first surviving paths. The node processing circuit 130 may calculate the path metric value PM of the selected unselected candidate path.

In the second stage S2 shown in FIG. 6B, candidate paths P₃¹, P₃², P₃³, and P₄¹ (the selected unselected candidate paths) are respectively expanded from the surviving paths P₁¹, P₁², P₁³, and P₂¹. The node processing circuit 130 may perform the “8-to-4 (that is, 2L-to-L) path competition” on the candidate paths P₁¹, P₁², P₁³, P₂¹, P₃¹, P₃², P₃³, and P₄¹ (the second candidate paths). In the path competition operation, the node processing circuit 130 may calculate the path metric value PM of each of the second candidate paths P₃¹, P₃², P₃³, and P₄¹. The node processing circuit 130 may select some paths from the second candidate paths P₁¹, P₁², P₁³, P₂¹, P₃¹, P₃², P₃³, and P₄¹ according to the path metric values PMs of the second candidate paths P₁¹, P₁², P₁³, P₂¹, P₃¹, P₃², P₃³, and P₄¹ to serve as multiple second surviving paths. The number of the second surviving paths is same as the number of the paths of the previous paths P11 to P14 (or the current paths P21 to P2L). It is assumed here that the candidate paths P₁¹, P₁², P₂¹, and P₃¹ survive after the path competition, as shown in FIG. 6B.

In a case where a certain surviving path (the target surviving path) of the second surviving paths P₁¹, P₁², P₂¹, and P₃¹ belongs to a certain path (the target previous path) of the previous paths P11 to P14, the node processing circuit 130 may select an unselected candidate path from the candidate paths of the target previous path according to the selection order of the target previous path to serve as one of multiple third candidate paths in the second stage S2.

In a third stage S3 shown in FIG. 6C, candidate paths P₅¹, P₅², P₆¹, and P₇¹ (the selected unselected candidate paths) are respectively expanded from the surviving paths P₁¹, P₁², P₂¹, and P₃¹. The node processing circuit 130 may perform the “8-to-4 (that is, 2L-to-L) path competition” on the candidate paths P₁¹, P₁², P₂¹, P₃¹, P₅¹, P₆¹, and P₇¹ (the third candidate paths). In the path competition operation, the node processing circuit 130 may calculate the path metric value PM of each of the third candidate paths P₅¹, P₅², P₆¹, and P₇¹. The node processing circuit 130 may select some paths from the third candidate paths P₁¹, P₁², P₂¹, P₃¹, P₅¹, P₆¹, and P₇¹ according to the path metric values PMs of the third candidate paths P₁¹, P₁², P₂¹, P₃¹, P₅¹, P₆¹, and P₇¹ to serve as multiple third surviving paths. It is assumed here that the candidate paths P₁¹, P₁², P₂¹, and P₅¹ survive after the path competition, as shown in FIG. 6C. As of now, the path competition operation of the current node is completed, and the third surviving paths P₁¹, P₁², P₂¹, and P₅¹ serve as the current paths P21 to P2L.

FIG. 7 is a schematic flowchart of an operation method of the polar code decoding apparatus 100 according to yet another embodiment of the disclosure. With reference to FIGS. 1 and 7, in Step S710, the path expanding circuit 120 may expand each of the multiple previous paths P11 to P1L corresponding to the previous decoding results into the multiple candidate paths according to the current node. According to the design requirements, reference may be made to the relevant description of the Step S320 shown in FIG. 3 (or the Step S410 shown in FIG. 4) for the Step S710 shown in FIG. 7, and (or) reference may be made to relevant description of the Step S710 shown in FIG. 7 for the Step S320 shown in FIG. 3. In some embodiments, the path expanding number E of a path expanding operation performed in the Step S710 shown in FIG. 7 may be min (2^{ε}, L) (with reference to the relevant description of the Step S310 shown in FIG. 3). In other embodiments, the path expanding number E of the path expanding operation performed in the Step S710 shown in FIG. 7 may be 2^{min (L-1,M)}, 2^{min (L,M-1)} or other numbers.

With reference to FIGS. 1, 2 and 7, in Step S720, the node processing circuit 130 may perform the path competition operation to select some paths from the candidate paths expanded from the previous paths P11 to P1L to serve as the multiple current paths P21 to P2L corresponding to the current decoding results. The path competition operation performed by the node processing circuit 130 in the Step S720 may include selecting at least one candidate path from the candidate paths of each of the previous paths P11 to P1L to serve as the multiple first candidate paths, calculating the path metric value PM of each of the first candidate paths, and selecting some paths from the first candidate paths to serve as the multiple first surviving paths according to the path metric values PMs of the first candidate paths. In the Step S720, the node processing circuit 130 may perform a normalization operation on the path metric values PMs of the L surviving paths (final surviving paths) that finally survived after the node is processed. According to the design requirements, reference may be made to the relevant description of the Step S720 shown in FIG. 7 for the Step S330 shown in FIG. 3. The normalization of the path metric values PMs may reduce complexity and decoding delay.

Using FIG. 6A as an illustrative example, in the third stage S3 shown in FIG. 6C, the node processing circuit 130 may perform the normalization operation on the path metric values PMs of the third candidate paths P₅¹, P₅², P₆¹, and P₇¹. A specific calculation manner of the normalization operation may be determined according to the design requirements. For example, in some embodiments, the node processing circuit 130 may calculate PMᵢ=PMᵢ−PMₘᵢₙ, so as to perform the normalization operation, where PMᵢ represents an i-th path metric value of an i-th surviving path in the path metric values PMs of the final surviving paths (for example, the third candidate paths P₅¹, P₅², P₆¹, and P₇¹), and PMₘᵢₙ represents a minimum path metric value of the path metric values PMs of the final surviving paths.

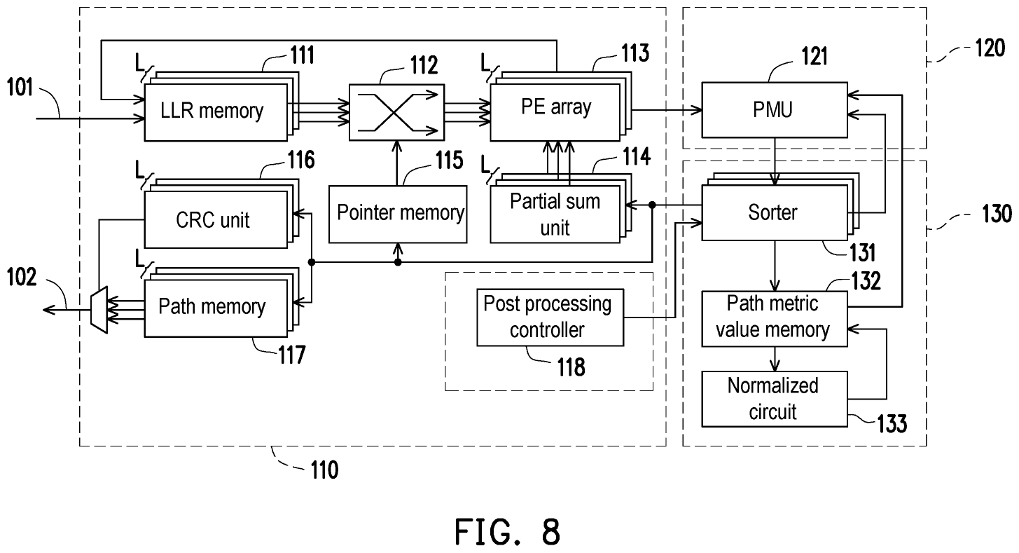

FIG. 8 is a schematic circuit block diagram illustrating the interface circuit 110, the path expanding circuit 120, and the node processing circuit 130 shown in FIG. 1 according to an embodiment of the disclosure. The schematic circuit block diagram shown in FIG. 8 may serve as a BRNW CA-LSC decoding device, where BRNW is bit-reliability based node-wise, CA-LSC is CRC-aided list successive cancellation, and CRC is cyclic redundancy check. Reference may be made to the relevant descriptions of the interface circuit 110, the path expanding circuit 120, and the node processing circuit 130 shown in FIG. 1 for the interface circuit 110, the path expanding circuit 120, and the node processing circuit 130 shown in FIG. 8. The path expanding circuit 120 and the node processing circuit 130 shown in FIG. 8 may implement the methods described in FIGS. 3, 4, and/or 7. That is, the circuit shown in FIG. 8 may implement bit-reliability based nodes (BRBN), bit-reliability based nodes processing (BRNP), and (or) path metric normalization (PMN).

In the embodiment shown in FIG. 8, the interface circuit 110 includes a log-likelihood ratio (LLR) memory 111, a cross-bar multiplexer 112, a processing element (PE) array 113, a partial sum unit (PSU) 114, a pointer memory 115, a cyclic redundancy check (CRC) unit 116, a path memory 117, and a post processing controller 118. The path expanding circuit 120 includes a path management unit (PMU) 121, and the node processing circuit 130 includes a sorter 131, a path metric value memory 132, and a normalized circuit 133.

The LLR memory 111 stores and provides the bit reliability (for example, the LLR) of N bits of the current node during a successive cancellation (SC) decoding process. In general, the list successive cancellation (LSC) decoding requires a L*N*Q_{LLR} bits (Q_{LLR} is a quantization bit of the LLR) memory (configured to determine a LLR interval during the SC decoding process), and N*Q_{ch} bits of memory (configured for a channel LLR value). Therefore, a total of L*N*Q_{LLR}+N*Q_{ch} bits of memory are required. In some embodiments, the node size M=8, number of the PE in each of the lists is 64, a stage number of the PE is SPE=log₂64=6, and area consumption is reduced by 2*L(2^{SPE}+2^{SPE}−1+ . . . +2^{SPE-log2M})Q=240LQ. Due to calculation in advance of LLR of some G nodes, decoding latency may also be reduced by N/2^{SPE+1}+N/2^{SPE}+ . . . +N/2^{log2M+1}=120 cycles.

There is an L-to-L cross-bar multiplexer 112 controlled by the pointer memory 115 between the PE array 113 and the LLR memory 111. As the order of the candidates in the list may change each time the node processing circuit 130 gives a new surviving path, therefore the cross-bar multiplexer 112 is responsible for providing the corresponding list LLR to the PE array 113. The partial sum unit (PSU) 114 is configured to store and calculate partial sum of the node calculate in the PE array 113. The partial sum unit (PSU) 114 may provide the partial sum for nodes that are required to be calculated in advance, and calculate the partial sum of a node with the node size M of up to 8. The path memory 117 and the CRC unit 116 successively store decision bits of each of the lists coming from the node processing circuit 130. The modules use the L-to-L cross-bar multiplexer 112 during decoding to enable the decision bits to continuously have a same list of candidates. At the end of decoding, the CRC unit 116 outputs legitimate signals, so as to select one of legal paths legal paths in the path memory 117 to serve as a decoded frame.

The path expanding circuit 120 and the node processing circuit 130 select the surviving path and the path metric value PM by calculating and sorting the path metric value PM according to the received node LLR. The path management unit 121 calculates the path metric value PM according to the current node type and decoding stage, and then the sorter 131 selects the best L paths and repeatedly feedbacks to the path management unit 121. It should be noted that the embodiment shown in FIG. 8 may only implement a 16-to-8 sorter 131 partially to prevent large area consumption.

The path metric value memory 132 is configured to store the path metric value PM. The normalized circuit 133 is coupled to the path metric value memory 132. The normalized circuit 133 performs a normalization operation on the path metric value PM in the path metric value memory 132, and updates a normalized operation result to the path metric value memory 132. For example, in some embodiments, the normalized circuit 133 may calculate PMᵢ=PMᵢ−PMₘᵢₙ, so as to perform the normalization operation.

According to different design requirements, implementation manners of the blocks of the interface circuit 110, the path expanding circuit 120, and/or the node processing circuit 130 may be through hardware, firmware, or software (that is, programs), or a combination thereof.

In terms of hardware, the blocks of the interface circuit 110, the path expanding circuit 120, and/or the node processing circuit 130 described above may be implemented in a logic circuit on an integrated circuit. The relevant functions of the interface circuit 110, the path expanding circuit 120, and/or the node processing circuit 130 may be implemented as the hardware using hardware description languages (for example, Verilog HDL or VHDL) or other suitable programming languages. For example, relevant functions of the interface circuit 110, the path expanding circuit 120, and/or the node processing circuit 130 may be implemented in one or more controllers, microcontrollers, microprocessors, application-specific integrated circuit (ASIC), digital signal processor (DSP), field programmable gate array (FPGA) and/or various logic blocks, modules, and circuits in other processing units.

In terms of software and/or firmware, the relevant functions of the interface circuit 110, the path expanding circuit 120, and/or the node processing circuit 130 may be implemented as a programming code. For example, general programming languages (such as C, C++ or an assembly language) or other suitable programming languages are used to implement the interface circuit 110, the path expanding circuit 120, and/or the node processing circuit 130. The programming code may be recorded/stored in a recording medium. In some embodiments, the recording medium includes, for example, a read only memory (ROM), a random access memory (RAM), and/or a storage device. The storage device includes a hard disk drive (HDD), a solid-state drive (SSD) or other storage devices. In other embodiments, the recording medium may include “non-transitory computer readable medium”, such as a tape, a disk, a card, a semiconductor memory, a programmable logic circuit, which may be used to implement the non-transitory computer readable medium. A computer, a central processing unit (CPU), a controller, a microcontroller, or a microprocessor may read and execute the programming code from the recording medium, thereby performing the relevant functions of the interface circuit 110, the path expanding circuit 120, and (or) the node processing circuit 130. Moreover, the programming code may also be provided to the computer (or the CPU) through any transmission medium (such as a communication network or broadcasting waves). The communication network is, for example, the Internet, a wired communication network, a wireless communication network, or other communication media.

In summary, the polar code decoding apparatus 100 and the operation method thereof in the foregoing embodiments can optimize the efficiency of polar code decoding to a maximum extent. A current node containing many reliable information bits is not required to expand into many candidate paths. In the case where “nodes with different reliabilities have the same path expanding number”, the conventional path expanding circuit may perform expansion of redundant paths (expand out into redundant candidate paths). It is conceivable that the redundant candidate paths will increase the hardware complexity and decoding delay. Therefore, in some embodiments, the path expanding circuit 120 may dynamically determine the path expanding number E of each of the previous paths P11 to P1L according to the unreliable information bit number c of the current node (for example, E=min(2^{ε}, L)), so as to reduce the redundant candidate paths as much as possible.

The conventional node processing circuit performs the path competition operation in an irregular manner, that is, the conventional node processing circuit has to process all of the candidate paths. The polar code decoding apparatus 100 may preferentially select a more reliable candidate path to undergo the path competition operation according to the path metric values PMs of the previous paths P11 to P1L and the LLR value of each bit of the current node. Therefore, the polar code decoding apparatus 100 can accurately and efficiently find out which of the candidate paths are more likely to be the correct paths.

The length of the critical path is related to the bit number of the path metric value PM. The node processing circuit 130 may perform the normalization operation on the path metric value PM of the candidate path to reduce the bit number of the path metric value PM. The normalization of the path metric value PM can reduce the complexity and decoding delay.

Although the disclosure has been disclosed with the foregoing exemplary embodiments, they are not intended to limit the disclosure. Any person skilled in the art can make various changes and modifications within the spirit and scope of the disclosure. Accordingly, the scope of the disclosure is defined by the claims appended hereto and the equivalents.

What is claimed is:

1. A polar code decoding apparatus, suitable for performing a polar code decoding of an encoded bit string, comprising:
a path expanding circuit, configured to expand each of a plurality of previous paths corresponding to a plurality of previous decoding results into a plurality of candidate paths according to a current node, wherein the encoded bit string is divided into a plurality of sub-bit strings to serve as a plurality of nodes comprising the current node, and the path expanding circuit is configured to dynamically determine a path expanding number of the plurality of candidate paths of each of the plurality of previous paths according to an unreliable information bit number of the current node; and
a node processing circuit, coupled to the path expanding circuit, and configured to perform a path competition operation to select some paths from the plurality of candidate paths to serve as a plurality of current paths corresponding to a plurality of current decoding results.

2. The polar code decoding apparatus according to claim 1, wherein each of a plurality of bits in the encoded bit string has a corresponding bit reliability, and each of the plurality of bits in the encoded bit string is classified as an information bit or a frozen bit according to the bit reliability.

3. The polar code decoding apparatus according to claim 2, wherein the bit reliability comprises a Bhattacharyya parameter.

4. The polar code decoding apparatus according to claim 2, wherein
a numerical range of the bit reliability is at least divided into a first sub-range and a second sub-range,
a current bit is classified as the information bit when the bit reliability of the current bit in the encoded bit string falls within the first sub-range, and
the current bit is classified as the frozen bit when the bit reliability of the current bit falls within the second sub-range.

5. The polar code decoding apparatus according to claim 4, wherein the first sub-range is first 50% of the numerical range, and the second sub-range is last 50% of the numerical range.

6. The polar code decoding apparatus according to claim 4, wherein
the first sub-range is at least divided into a third sub-range and a fourth sub-range,
the current bit is classified as a reliable information bit when the bit reliability of the current bit falls within the third sub-range,
the current bit is classified as an unreliable information bit when the bit reliability of the current bit falls within the fourth sub-range, and
the unreliable information bit number of the current node is a number of bits classified as the unreliable information bit in the current node.

7. The polar code decoding apparatus according to claim 6, wherein the third sub-range is 72.54% of the first sub-range, and the fourth sub-range is remaining 27.46% of the first sub-range.

8. The polar code decoding apparatus according to claim 1, wherein the path expanding number E=min (2^{ε}, L), where min( ) represents a “minimum value” function, ε represents a number of bits classified as an unreliable information bit in the current node, and L represents a path number of the plurality of previous paths or a path number of the plurality of current paths.

9. The polar code decoding apparatus according to claim 1, wherein the path competition operation performed by the node processing circuit comprises:
selecting some paths from the plurality of candidate paths to serve as the plurality of current paths according to a path metric value of each of the plurality of previous paths and a log-likelihood ratio of each of a plurality of bits of the current node.

10. The polar code decoding apparatus according to claim 9, wherein the path competition operation performed by the node processing circuit further comprises:
sorting the plurality of previous paths according to the plurality of path metric values of the plurality of previous paths;
sorting the plurality of candidate paths of each of the plurality of previous paths according to the log-likelihood ratios of the plurality of bits of the current node, so as to determine a selection order of the plurality of candidate paths of each of the plurality of previous paths;
selecting at least one candidate path from the plurality of candidate paths of each of the plurality of previous paths according to the selection order of each of the plurality of previous paths to serve as a plurality of first candidate paths;
calculating a path metric value of each of the plurality of first candidate paths; and
selecting some paths from the plurality of first candidate paths according to the plurality of path metric values of the plurality of first candidate paths to serve as a plurality of first surviving paths.

11. The polar code decoding apparatus according to claim 10, wherein a number of the plurality of first surviving paths is same as a path number of the plurality of previous paths or a path number of the plurality of current paths.

12. The polar code decoding apparatus according to claim 10, wherein the path competition operation performed by the node processing circuit further comprises:
selecting an unselected candidate path from the plurality of candidate paths of a target previous path according to the selection order of the target previous path to serve as one of a plurality of second candidate paths in a case where a target surviving path in the plurality of first surviving paths belongs to a target previous path in the plurality of previous paths, wherein the plurality of second candidate paths also comprise the plurality of first surviving paths;
calculating a path metric value of the selected unselected candidate path; and
selecting some paths from the plurality of second candidate paths according to the plurality of path metric values of the plurality of second candidate paths to serve as a plurality of second surviving paths.

13. The polar code decoding apparatus according to claim 12, wherein a number of the plurality of second surviving paths is same as a path number of the plurality of previous paths or a path number of the plurality of current paths.

14. The polar code decoding apparatus according to claim 10, further comprising:
performing a normalization operation on the plurality of path metric values of a plurality of final surviving paths.

15. The polar code decoding apparatus according to claim 14, wherein the normalization operation comprises:
calculating PMᵢ=PMᵢ−PMₘᵢₙ, where PMᵢ represents an i-th path metric value of an i-th surviving path in the plurality of path metric values of the plurality of final surviving paths, and PMₘᵢₙ represents a minimum path metric value of the plurality of path metric values of the plurality of final surviving paths.

16. The polar code decoding apparatus according to claim 14, further comprising:
a path metric value memory, configured to store the plurality of path metric values; and
a normalized circuit, coupled to the path metric value memory, wherein the normalized circuit performs the normalization operation on the plurality of path metric values in the path metric value memory, and updates a normalized operation result to the path metric value memory.

17. An operation method of a polar code decoding apparatus, the polar code decoding apparatus is suitable for performing a polar code decoding of an encoded bit string, the operation method comprising:
expanding each of a plurality of previous paths corresponding to a plurality of previous decoding results into a plurality of candidate paths by a path expanding circuit according to a current node, wherein the encoded bit string is divided into a plurality of sub-bit strings to serve as a plurality of nodes comprising the current node;
dynamically determining a path expanding number of the plurality of candidate paths of each of the plurality of previous paths by the path expanding circuit according to an unreliable information bit number of the current node; and
performing a path competition operation by a node processing circuit to select some paths from the plurality of candidate paths to serve as a plurality of current paths corresponding to a plurality of current decoding results.

18. The operation method according to claim 17, wherein each of a plurality of bits in the encoded bit string has a corresponding bit reliability, and each of the plurality of bits in the encoded bit string is classified as an information bit or a frozen bit according to the bit reliability.

19. The operation method according to claim 18, wherein the bit reliability comprises a Bhattacharyya parameter.

20. The operation method according to claim 18, wherein a numerical range of the bit reliability is at least divided into a first sub-range and a second sub-range, the operation method further comprising:
classifying a current bit as the information bit when the bit reliability of the current bit in the encoded bit string falls within the first sub-range, and
classifying the current bit as the frozen bit when the bit reliability of the current bit falls within the second sub-range.

21. The operation method according to claim 20, wherein the first sub-range is first 50% of the numerical range, and the second sub-range is last 50% of the numerical range.

22. The operation method according to claim 20, wherein the first sub-range is at least divided into a third sub-range and a fourth sub-range, the operation method further comprising:
classifying the current bit as a reliable information bit when the bit reliability of the current bit falls within the third sub-range, and
classifying the current bit as an unreliable information bit when the bit reliability of the current bit falls within the fourth sub-range, wherein the unreliable information bit number of the current node is a number of bits classified as the unreliable information bit in the current node.

23. The operation method according to claim 22, wherein the third sub-range is 72.54% of the first sub-range, and the fourth sub-range is remaining 27.46% of the first sub-range.

24. The operation method according to claim 17, wherein the path expanding number E=min(2^{ε}, L), where min( ) represents a “minimum value” function, ε represents a number of bits classified as an unreliable information bit in the current node, and L represents a path number of the plurality of previous paths or a path number of the plurality of current paths.

25. A polar code decoding apparatus, suitable for performing a polar code decoding of an encoded bit string, comprising:
a path expanding circuit, configured to expand each of a plurality of previous paths corresponding to a plurality of previous decoding results into a plurality of candidate paths according to a current node, wherein the encoded bit string is divided into a plurality of sub-bit strings to serve as a plurality of nodes comprising the current node, and the path expanding circuit is configured to dynamically determine a path expanding number of the plurality of candidate paths of each of the plurality of previous paths according to an unreliable information bit number of the current node; and
a node processing circuit, coupled to the path expanding circuit, and configured to perform a path competition operation to select some paths from the plurality of candidate paths to serve as a plurality of current paths corresponding to a plurality of current decoding results, wherein the path competition operation performed by the node processing circuit comprises:
selecting some paths from the plurality of candidate paths to serve as the plurality of current paths according to a path metric value of each of the plurality of previous paths and a log-likelihood ratio of each of a plurality of bits of the current node.

26. The polar code decoding apparatus according to claim 25, wherein the path competition operation performed by the node processing circuit further comprises:
sorting the plurality of previous paths according to the plurality of path metric values of the plurality of previous paths;
sorting the plurality of candidate paths of each of the plurality of previous paths according to the log-likelihood ratios of the plurality of bits of the current node, so as to determine a selection order of the plurality of candidate paths of each of the plurality of previous paths;
selecting at least one candidate path from the plurality of candidate paths of each of the plurality of previous paths according to the selection order of each of the plurality of previous paths to serve as a plurality of first candidate paths;
calculating a path metric value of each of the plurality of first candidate paths; and
selecting some paths from the plurality of first candidate paths according to the plurality of path metric values of the plurality of first candidate paths to serve as a plurality of first surviving paths.

27. The polar code decoding apparatus according to claim 26, wherein a number of the plurality of first surviving paths is same as a path number of the plurality of previous paths or a path number of the plurality of current paths.

28. The polar code decoding apparatus according to claim 26, wherein the path competition operation performed by the node processing circuit further comprises:
selecting an unselected candidate path from the plurality of candidate paths of a target previous path according to the selection order of the target previous path to serve as one of a plurality of second candidate paths in a case where a target surviving path in the plurality of first surviving paths belongs to a target previous path in the plurality of previous paths, wherein the plurality of second candidate paths also comprise the plurality of first surviving paths;
calculating a path metric value of the selected unselected candidate path; and
selecting some paths from the plurality of second candidate paths according to the plurality of path metric values of the plurality of second candidate paths to serve as a plurality of second surviving paths.

29. The polar code decoding apparatus according to claim 28, wherein a number of the plurality of second surviving paths is same as a path number of the plurality of previous paths or a path number of the plurality of current paths.

30. The polar code decoding apparatus according to claim 26, further comprising:
performing a normalization operation on the plurality of path metric values of a plurality of final surviving paths.

31. The polar code decoding apparatus according to claim 30, wherein the normalization operation comprises:
calculating PMᵢ=PMᵢ−PMₘᵢₙ, where PMᵢ represents an i-th path metric value of an i-th surviving path in the plurality of path metric values of the plurality of final surviving paths, and PMₘᵢₙ represents a minimum path metric value of the plurality of path metric values of the plurality of final surviving paths.

32. The polar code decoding apparatus according to claim 30, further comprising:
a path metric value memory, configured to store the plurality of path metric values; and
a normalized circuit, coupled to the path metric value memory, wherein the normalized circuit performs the normalization operation on the plurality of path metric values in the path metric value memory, and updates a normalized operation result to the path metric value memory.

33. An operation method of a polar code decoding apparatus, the polar code decoding apparatus is suitable for performing a polar code decoding of an encoded bit string, the operation method comprising:
expanding each of a plurality of previous paths corresponding to a plurality of previous decoding results into a plurality of candidate paths by a path expanding circuit according to a current node, wherein the encoded bit string is divided into a plurality of sub-bit strings to serve as a plurality of nodes comprising the current node; and
performing a path competition operation by a node processing circuit to select some paths from the plurality of candidate paths to serve as a plurality of current paths corresponding to a plurality of current decoding results, wherein the path competition operation performed by the node processing circuit comprises:
selecting some paths from the plurality of candidate paths to serve as the plurality of current paths according to a path metric value of each of the plurality of previous paths and a log-likelihood ratio of each of a plurality of bits of the current node.

34. The operation method according to claim 33, wherein the path competition operation performed by the node processing circuit further comprises:
sorting the plurality of previous paths according to the plurality of path metric values of the plurality of previous paths;
sorting the plurality of candidate paths of each of the plurality of previous paths according to the log-likelihood ratios of the plurality of bits of the current node, so as to determine a selection order of the plurality of candidate paths of each of the plurality of previous paths;
selecting at least one candidate path from the plurality of candidate paths of each of the plurality of previous paths according to the selection order of each of the plurality of previous paths to serve as a plurality of first candidate paths;
calculating a path metric value of each of the plurality of first candidate paths; and
selecting some paths from the plurality of first candidate paths according to the plurality of path metric values of the plurality of first candidate paths to serve as a plurality of first surviving paths.

35. The operation method according to claim 34, wherein a number of the plurality of first surviving paths is same as a path number of the plurality of previous paths or a path number of the plurality of current paths.

36. The operation method according to claim 34, wherein the path competition operation performed by the node processing circuit further comprises:
selecting an unselected candidate path from the plurality of candidate paths of a target previous path according to the selection order of the target previous path to serve as one of a plurality of second candidate paths in a case where a target surviving path in the plurality of first surviving paths belongs to a target previous path in the plurality of previous paths, wherein the plurality of second candidate paths also comprise the plurality of first surviving paths;
calculating a path metric value of the selected unselected candidate path; and
selecting some paths from the plurality of second candidate paths according to the plurality of path metric values of the plurality of second candidate paths to serve as a plurality of second surviving paths.

37. The operation method according to claim 36, wherein a number of the plurality of second surviving paths is same as a path number of the plurality of previous paths or a path number of the plurality of current paths.

38. A polar code decoding apparatus, suitable for performing a polar code decoding of an encoded bit string, comprising:
a path expanding circuit, configured to expand each of a plurality of previous paths corresponding to a plurality of previous decoding results into a plurality of candidate paths according to a current node, wherein the encoded bit string is divided into a plurality of sub-bit strings to serve as a plurality of nodes comprising the current node, and the path expanding circuit is configured to dynamically determine a path expanding number of the plurality of candidate paths of each of the plurality of previous paths according to an unreliable information bit number of the current node; and
a node processing circuit, coupled to the path expanding circuit, and configured to perform a path competition operation to select some paths from the plurality of candidate paths to serve as a plurality of current paths corresponding to a plurality of current decoding results, wherein the path competition operation performed by the node processing circuit comprises:
selecting at least one candidate path from the plurality of candidate paths of each of the plurality of previous paths to serve as a plurality of first candidate paths;
calculating a path metric value of each of the plurality of first candidate paths;
selecting some paths from the plurality of first candidate paths according to the plurality of path metric values of the plurality of first candidate paths to serve as a plurality of first surviving paths; and
performing a normalization operation on the plurality of path metric values of a plurality of final surviving paths.

39. The polar code decoding apparatus according to claim 38, wherein the normalization operation comprises:
calculating PMᵢ=PMᵢ−PMₘᵢₙ, where PMᵢ represents an i-th path metric value of an i-th surviving path in the plurality of path metric values of the plurality of final surviving paths, and PMₘᵢₙ represents a minimum path metric value of the plurality of path metric values of the plurality of final surviving paths.

40. The polar code decoding apparatus according to claim 38, further comprising:
a path metric value memory, configured to store the plurality of path metric values; and
a normalized circuit, coupled to the path metric value memory, wherein the normalized circuit performs the normalization operation on the plurality of path metric values in the path metric value memory, and updates a normalized operation result to the path metric value memory.

41. An operation method of a polar code decoding apparatus, the polar code decoding apparatus is suitable for performing a polar code decoding of an encoded bit string, the operation method comprising:
expanding each of a plurality of previous paths corresponding to a plurality of previous decoding results into a plurality of candidate paths by a path expanding circuit according to a current node, wherein the encoded bit string is divided into a plurality of sub-bit strings to serve as a plurality of nodes comprising the current node; and
performing a path competition operation by a node processing circuit to select some paths from the plurality of candidate paths to serve as a plurality of current paths corresponding to a plurality of current decoding results, wherein the path competition operation performed by the node processing circuit comprises:
selecting at least one candidate path from the plurality of candidate paths of each of the plurality of previous paths to serve as a plurality of first candidate paths;
calculating a path metric value of each of the plurality of first candidate paths;
selecting some paths from the plurality of first candidate paths according to the plurality of path metric values of the plurality of first candidate paths to serve as a plurality of first surviving paths; and
performing a normalization operation on the plurality of path metric values of a plurality of final surviving paths.

42. The operation method according to claim 41, wherein the normalization operation comprises:
calculating PMᵢ=PMᵢ−PMₘᵢₙ, where PMᵢ represents an i-th path metric value of an i-th surviving path in the plurality of path metric values of the plurality of final surviving paths, and PMₘᵢₙ represents a minimum path metric value of the plurality of path metric values of the plurality of final surviving paths.
